(19) United States
(12) Patent Application Publication
(10) Pub. No.: US 2014/0312341 A1
(43) Pub. Date: Oct. 23, 2014

(54) Transistor, the Preparation Method Therefore, and Display Panel

(71) Applicant: Shenzhen China Star Optoelectronics Technology Co. Ltd., Shenzhen, Guangdong (CN)

(72) Inventors: Cheng-Lung Chiang, Shenzhen City (CN); Po-Lin Chen, Shenzhen City (CN)

(73) Assignee: Shenzhen China Star Optoelectronics Technology Co., Ltd., Shenzhen, Guandong (CN)

(21) Appl. No.: 13/884,299

(22) PCT Filed: Apr. 24, 2013
(86) PCT No.: PCT/CN13/74598

§ 371 Date: May 9, 2013

(30) Foreign Application Priority Data
Apr. 22, 2013 (CN) 201310140575.9

(51) Int. Cl. H01L 29/786; H01L 29/66; H01L 21/66

(52) U.S. Cl. CPC H01L 29/7869; H01L 22/12; H01L 29/66969
USPC 257/43; 438/5

(57) ABSTRACT

The present invention discloses a transistor, the preparation method thereof, and a display panel. The transistor comprises: a gate electrode; a gate insulating layer covering the gate electrode; an oxide semiconductor layer formed on the gate insulating layer; a first protective layer formed on the oxide semiconductor layer; a source/drain electrode connected with the oxide semiconductor layer; and a second protective layer covering the source/drain electrode; wherein, the hydrogen atom content per unit volume of the first protective layer is less than that of the gate insulating layer, and the hydrogen atom content per unit volume of the gate insulating layer is less than that of the second protective layer. Through the above solutions, the present invention can suppress the combination of the oxygen atom of the semiconductor layer in the transistor and the external hydrogen atom, to improve the performance and stability of the device.

### BACKGROUND OF THE INVENTION

1. Field of the Invention

The present invention relates to the field of transistor, the preparation methods thereof, and display panel.

2. The Related Arts

Each pixel of an active matrix screen display is driven by the thin film transistor (TFT) which is integrated behind the pixel. Therefore, it can deal with high-speed, high-brightness, high-contrast display screen information. Each pixel of the active matrix flat panel display is controlled by the thin film transistor which is integrated on itself, which is active pixel.

The thin film transistor usually comprises a gate electrode, a gate insulating layer, a source/drain electrode, a semiconductor layer, a first protective layer and a second protective layer, and the semiconductor layer usually utilizes indium gallium zinc oxide (IGZO). The “O” of IGZO usually combines with the external hydrogen, thereby, causing the deterioration of the device characteristic and stability.

### SUMMARY OF THE INVENTION

The technical issue to be solved by the present invention is to provide a transistor, the preparation method thereof and a display panel, which can suppress the combination of the oxygen atom of the semiconductor layer in the transistor and the external hydrogen atom, to improve the performance and stability of the device.

To solve the above technical issue, a technical method provided by the present invention is: providing a transistor, which comprises: a gate electrode; a gate insulating layer covering the gate electrode; an oxide semiconductor layer formed on the gate insulating layer; a first protective layer formed on the oxide semiconductor layer; a source/drain electrode connected with the oxide semiconductor layer; and a second protective layer covering the source/drain electrode; wherein, the hydrogen atom content per unit volume of the first protective layer is less than that of the gate insulating layer, the hydrogen atom content per unit volume of the gate insulating layer is less than that of the second protective layer.

Wherein, the gate insulating layer is a silicon oxide layer with the hydrogen atom content per unit volume between 5% and 10%.

Wherein, the first protective layer is a silicon oxide layer with the hydrogen atom content per unit volume between 0% and 5%.

Wherein, the second protective layer is a silicon nitride layer with the hydrogen atom content per unit volume more than 20%.

To solve the above technical issue, another technical method provided by the present invention is: providing a display panel, which comprises a transistor. The transistor comprises: a gate electrode; a gate insulating layer covering the gate electrode; an oxide semiconductor layer formed on the gate insulating layer; a first protective layer formed on the oxide semiconductor layer; a source/drain electrode connected with the oxide semiconductor layer; and a second protective layer covering the source/drain electrode; wherein, the hydrogen atom content per unit volume of the first protective layer is less than that of the gate insulating layer, the hydrogen atom content per unit volume of the gate insulating layer is less than that of the second protective layer.

Wherein, the gate insulating layer is a silicon oxide layer with the hydrogen atom content per unit volume between 5% and 10%.

Wherein, the first protective layer is a silicon oxide layer with the hydrogen atom content per unit volume between 0% and 5%.

Wherein, the second protective layer is a silicon nitride layer with the hydrogen atom content per unit volume more than 20%.

To solve the above technical issue, another technical method provided by the present invention is providing a preparation method of the transistor, which comprises: forming a gate electrode on a substrate; forming a gate insulating layer on the gate electrode, which covers the gate electrode; forming an oxide semiconductor layer on the gate insulating layer; forming a first protective layer on the oxide semiconductor layer, controlling the hydrogen atom content per unit volume of the protective layer less than that of the gate insulating layer; forming a source/drain electrode on the first protective layer; and forming a second protective layer on the source/drain electrode, which covers the source/drain electrode, controlling the hydrogen atom content per unit volume of the second protective layer more than that of the gate insulating layer.

Wherein, the step of forming a gate insulating layer on the gate electrode, which covers the gate electrode comprises: utilizing the mixed gas of TEOS or SiH₄ mixed with at least one of N₂O, N₂, O₂, and O₃ to form the gate insulating layer with the hydrogen atom content per unit volume between 5% and 10% on the gate electrode through the chemical vapor deposition method, which covers the gate electrode; the step of forming a first protective layer on the oxide semiconductor layer comprises: utilizing the mixed gas of TEOS or SiH₄ mixed with at least one of N₂O, N₂, O₂, and O₃ to form the first protective layer with the hydrogen atom content per unit volume between 0% and 5% on the oxide semiconductor layer through the chemical vapor deposition method.

Wherein, the step of forming a second protective layer on the source/drain electrode, which covers the source/drain electrode comprises: utilizing the mixed gas of SiH₄, N₂, and NH₃ to form the second protective layer with the hydrogen atom content per unit volume more than 20% on the source/drain electrode through the chemical vapor deposition method, which covers the source/drain electrode.

The benefit in the present invention is as follows. To distinguish it from the case of the prior art, the present invention controls the hydrogen atom content per unit volume of the first protective layer in the transistor less than that of the gate insulating layer, and controls the hydrogen atom content per unit volume of the gate insulating layer less than that of the second protective layer, which allows the relationship of the hydrogen atom content per unit volume within the first protective layer, the gate insulating layer and the second protective layer to be the second protective layer>the gate insulating layer>the first protective layer. Thereby, it can greatly enhance the performance and stability of the display device.

### BRIEF DESCRIPTION OF THE DRAWINGS

FIG. 1 is a schematic structural diagram of a transistor according to an embodiment of the present invention.

FIG. 2 is a flowchart of the preparation method of the transistor according to an embodiment of the present invention.

### DETAILED DESCRIPTION OF THE PREFERRED EMBODIMENTS

Transistor is one kind of the field effect transistor. The roughly producing way is to deposit various thin films, such as semiconductor active layer, dielectric layer and metal electrode layer, on the substrate.

Transistor is to deposit a thin film on the substrate (if it is applied in liquid crystal display, the glass substrate is mostly utilized) as a channel region.

Most transistor utilizes the hydrogenated amorphous silicon (a-Si: H) as the main material, due to its band gap less than monocrystalline silicon (Eg=1.12 eV). And because it utilizes the a-Si: H as the main material, the TFT is mostly not transparent. Moreover, the TFT often utilizes the indium tin oxide (ITO) in the dielectric, the electrode and the internal wiring. The ITO is a transparent material.

Because the oxide semiconductor layer in the transistor usually utilizes IGZO material, the “O” in the IGZO may combine with the external hydrogen, which will easily affect the characteristic and stability of the display device. Therefore, how to control the hydrogen atom content per unit volume of each structure layer in the transistor has great significance for improving the performance and stability of the device.

The present invention provides a transistor, which can suppress the combination of the oxygen atom of the semiconductor layer in the transistor and the external hydrogen atom, to improve the performance and stability of the device.

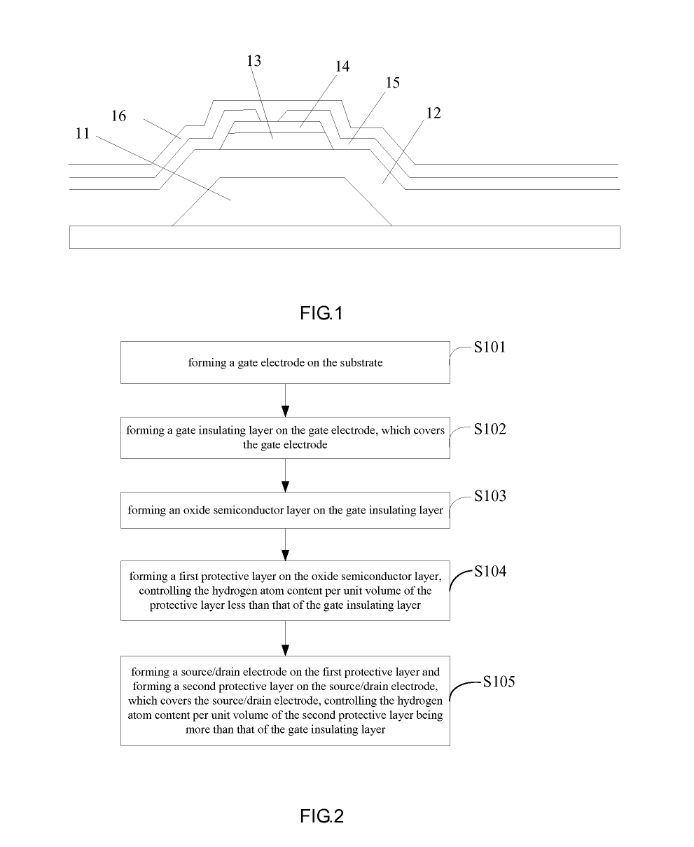

Referring to FIG. 1, FIG. 1 is an schematic structural diagram of a transistor according to an embodiment of the present invention, the transistor comprises:

a gate electrode 11; a gate insulating layer 12 covering the gate electrode 11; an oxide semiconductor layer 13 formed on the gate insulating layer 12; a first protective layer 14 formed on the oxide semiconductor layer 13; a source/drain electrode 15 connected with the oxide semiconductor layer 13; and a second protective layer 16 covering the source/drain electrode 15; wherein, the hydrogen atom content per unit volume of the first protective layer 14 is less than that of the gate insulating layer 12.

Wherein, the gate insulating layer 12 and the first protective layer 14 are composed of the silicon oxide (SiOₓ). The embodiment of the present invention is to utilize the mixed gas of TEAS or SiH₄ mixed with at least one of N₂O, N₂, O₂, and O₃ to form film by plasma enhanced chemical vapor deposition (PECVD). If the first protective layer 14 and the gate insulating layer 12 contain the higher hydrogen atom (H) content, it will cause the electrical deterioration of the transistor. In particular to the process of forming the first protective layer 14, the oxide semiconductor is directly exposed to the plasma. Therefore, in the process of forming the first protective layer 14, the present invention utilizes the mixed gas of N₂O, N₂, O₂, O₃ with higher flow rate mixed with TEOS or SiH₄ to reduce the hydrogen atom content per unit volume of the formed first protective layer 14. Controlling the hydrogen atom content per unit volume of the first protective layer 14 being less than that of the gate insulating layer 12 can improve the performance and stability of the transistor.

In preferred aspect, the embodiment of the present invention controls the hydrogen atom content per unit volume of the first protective layer 14 being between 0% and 5%, such as 2% or 4%, etc., and controls the hydrogen atom content per unit volume of the gate insulating layer 12 being between 5% and 10%, such as 6% or 8%. etc.

In order to further improve the performance of the transistor, control the hydrogen atom content per unit volume of the gate insulating layer 12 being less than the second protective layer 16.

The second protective layer 16 is used to reduce the influence of ambient moisture and oxygen for transistor. Therefore, it is preferred to utilize silicon nitride (SiNₓ). The embodiment of the present invention forms the film utilizing the mixed gas of SiH₄, N₂, NH₃ through the chemical vapor deposition. Therefore, the hydrogen atom content per unit volume of the formed second protective layer 16 is much more than the gate insulating layer 12. In the embodiment of the present invention, control the hydrogen atom content per unit volume of the second protective layer 16 being more than 20%, such as 25% or 30%, etc.

Through the descriptions as above, it can be understood that the present invention can suppress the combination of the oxygen atom of the semiconductor layer in the transistor and the external hydrogen atom by controlling the hydrogen atom content of the first protective layer in the transistor being less than the gate insulating layer, which improves the performance and stability of the device.

Furthermore, it controls the hydrogen atom content per unit volume of the gate insulating layer less than that of the second protective layer, which allows the relationship of the hydrogen atom content per unit volume within the first protective layer, the gate insulating layer and the second protective layer to be the second protective layer>the gate insulating layer>the first protective layer. Thereby, it can greatly enhance the performance and stability of the display device.

The present invention also provides the preparation method of the transistor, referring to FIG. 2. It is a flowchart of the preparation method of the transistor according to an embodiment of the present invention. The preparation method of the transistor comprises the following steps.

Step S101: forming a gate electrode on the substrate.

Form the gate electrode on the substrate such as glass substrate. The gate electrode is the electrode which provides the gate voltage to the transistor. The gate electrode is copper, aluminum, molybdenum, titanium, or the laminated structure thereof formed by sputtering and mask process The thickness of the gate electrode can be controlled between 50-200 nm, such as 100 nm or 150 nm.

Step S102: forming a gate insulating layer on the gate electrode, which covers the gate electrode.

On the gate electrode, form the gate insulating layer which covers the whole gate electrode. The gate insulating layer can be formed from silicon oxide film, silicon nitride film, silicon nitride oxide film, etc. The gate insulating layer according to the embodiment of the present invention is formed utilizing the mixed gas of TEOS or SiH₄ mixed with at least one of N₂O, N₂, O₂, and O₃ through plasma enhanced chemical vapor deposition (PECVD). The thickness of the gate electrode according to the embodiment of the present invention can be controlled between 50-200 nm, such as 100 nm or 120 nm. In order to improve the performance and stability of the device, the embodiment of the present invention controls the hydrogen atom content per unit volume of the gate insulating layer being between 5% and 10%, such as 6% or 8%, etc. There are many ways to control the hydrogen atom content per unit volume of the gate insulating layer, which is not strictly limited in the present invention. For example, control the hydrogen atom content per unit volume of the gate insulating layer through adjusting the flow rate ratio of N₂O/SiH₄.

Step S103: forming an oxide semiconductor layer on the gate insulating layer.

On the gate insulating layer, form the oxide semiconductor layer through sputtering and mask process. The oxide semiconductor layer comprises at least one of zinc oxide, tin oxide, indium oxide and gallium oxide.

Step S104: forming a first protective layer on the oxide semiconductor layer, controlling the hydrogen atom content per unit volume of the protective layer less than that of the gate insulating layer.

The first protective layer is formed on the oxide semiconductor layer by chemical vapor deposition. The first protective layer according to the embodiment of the present invention is formed utilizing the mixed gas of TEOS or SiH₄ mixed with N₂O, N₂, O₂, and O₃ through plasma enhanced chemical vapor deposition (PECVD). If the first protective layer and the gate insulating layer contain the higher hydrogen atom (H) content, it will cause the electrical deterioration of the transistor. In particular to the process of forming the first protective layer, the oxide semiconductor is directly exposed to the plasma. Therefore, in the process of forming the first protective layer, the present invention utilizes the mixed gas of N₂O, N₂, O₂, O₃ with higher flow rate mixed with TEOS or SiH₄ to reduce the hydrogen atom content per unit volume of the formed first protective layer. Controlling the hydrogen atom content per unit volume of the first protective layer being less than that of the gate insulating layer can improve the performance and stability of the transistor.
Controlling the hydrogen atom content per unit volume of the first protective layer being less than that of the gate insulating layer can improve the performance and stability of the transistor.

In a preferred aspect, the embodiment of the present invention controls the hydrogen atom content per unit volume of the first protective layer 14 being between 0% and 5%, such as 2% or 4%, etc.

Step S105: forming a source/drain electrode on the first protective layer and forming a second protective layer on the source/drain electrode, which covers the source/drain electrode, controlling the hydrogen atom content per unit volume of the second protective layer being more than that of the gate insulating layer.

On the other hand, the preparation method of the transistor further comprises forming the source/drain electrode on the first protective layer; and forming a second protective layer on the source/drain electrode, which covers the source/drain electrode, controlling the hydrogen atom content per unit volume of the second protective layer being more than that of the gate insulating layer.

The second protective layer is used to reduce the influence of ambient moisture and oxygen for transistor. Therefore, it is preferred to utilize silicon nitride (SiNₓ). The embodiment of the present invention forms the film utilizing the mixed gas of SiH₄, N₂, NH₃ through the chemical vapor deposition. Therefore, the hydrogen atom content per unit volume of the formed second protective layer is much more than the gate insulating layer. In the embodiment of the present invention, control the hydrogen atom content per unit volume of the second protective layer 16 being more than 20%, such as 25% or 30%, etc.

The above technical solution can suppress the combination of the oxygen atom of the semiconductor layer in the transistor and the external hydrogen atom through controlling the hydrogen atom content of the first protective layer in the transistor being less than that of the gate insulating layer, which improves the performance and stability of the device.

Furthermore, it controls the hydrogen atom content per unit volume of the gate insulating layer less than that of the second protective layer, which allows the relationship of the hydrogen atom content per unit volume within the first protective layer, the gate insulating layer and the second protective layer to be the second protective layer>the gate insulating layer>the first protective layer. Thereby, it can greatly enhance the performance and stability of the display device.

The preferred embodiments according to the present invention are mentioned above, which cannot be used to define the scope of the right of the present invention. Those modifications and variations are considered encompassed in the scope of protection defined by the clams of the present invention.

What is claimed is:

1. A transistor, wherein, it comprises:
a gate electrode;
a gate insulating layer, covering the gate electrode;
an oxide semiconductor layer, formed on the gate insulating layer;
a first protective layer, formed on the oxide semiconductor layer;
a source/drain electrode, connected with the oxide semiconductor layer; and
a second protective layer, covering the source/drain electrode;
wherein, the hydrogen atom content per unit volume of the first protective layer is less than that of the gate insulating layer, the hydrogen atom content per unit volume of the gate insulating layer is less than that of the second protective layer.

2. The transistor as claimed in claim 1, wherein, the gate insulating layer is a silicon oxide layer with the hydrogen atom content per unit volume between 5% and 10%.

3. The transistor as claimed in claim 1, wherein, the first protective layer is a silicon oxide layer with the hydrogen atom content per unit volume between 0% and 5%.

4. The transistor as claimed in claim 1, wherein, the second protective layer is a silicon nitride layer with the hydrogen atom content per unit volume more than 20%.

5. A display panel, wherein, it comprises a transistor, which comprises:
a gate electrode;
a gate insulating layer, covering the gate electrode;
an oxide semiconductor layer, formed on the gate insulating layer;
a first protective layer, formed on the oxide semiconductor layer;
a source/drain electrode, connected with the oxide semiconductor layer; and
a second protective layer, covering the source/drain electrode;
wherein, the hydrogen atom content per unit volume of the first protective layer is less than that of the gate insulating layer, the hydrogen atom content per unit volume of the gate insulating layer is less than that of the second protective layer.

6. The display panel as claimed in claim 5, wherein, the gate insulating layer is a silicon oxide layer with the hydrogen atom content per unit volume between 5% and 10%.

7. The display panel as claimed in claim 5, wherein, the first protective layer is a silicon oxide layer with the hydrogen atom content per unit volume between 0% and 5%.

8. The display panel as claimed in claim 5, wherein, the second protective layer is a silicon nitride layer with the hydrogen atom content per unit volume more than 20%.

9. An preparation method of transistor, wherein, it comprises:
forming a gate electrode on a substrate;
forming a gate insulating layer on the gate electrode, which covers the gate electrode;
forming an oxide semiconductor layer on the gate insulating layer;
forming a first protective layer on the oxide semiconductor layer, controlling the hydrogen atom content per unit volume of the protective layer less than that of the gate insulating layer;
forming a source/drain electrode on the first protective layer; and
forming a second protective layer on the source/drain electrode, which covers the source/drain electrode, controlling the hydrogen atom content per unit volume of the second protective layer more than that of the gate insulating layer.

10. The preparation method as claimed in claim 9, wherein,
the step of forming a gate insulating layer on the gate electrode, which covers the gate electrode comprises:
utilizing the mixed gas of TEOS or SiH₄ mixed with at least one of N₂O, N₂, O₂, and O₃ to form the gate insulating layer with the hydrogen atom content per unit volume between 5% and 10% on the gate electrode through the chemical vapor deposition method, which covers the gate electrode;
the step of forming a first protective layer on the oxide semiconductor layer comprises:
utilizing the mixed gas of TEOS or SiH₄ mixed with at least one of N₂O, N₂, O₂, and O₃ to form the first protective layer with the hydrogen atom content per unit volume between 0% and 5% on the oxide semiconductor layer through the chemical vapor deposition method.

11. The preparation method as claimed in claim 9, wherein,
the step of forming a second protective layer on the source/drain electrode, which covers the source/drain electrode comprises:
utilizing the mixed gas of SiH₄, N₂, and NH₃ to form the second protective layer with the hydrogen atom content per unit volume more than 20% on the source/drain electrode through the chemical vapor deposition method, which covers the source/drain electrode.
